(19) United States
(12) Patent Application Publication
(10) Pub. No.: US 2026/0013037 A1
(43) Pub. Date: Jan. 8, 2026

(54) PRINTED CIRCUIT BOARD VENDOR BACKDRILLING CAPABILITY QUALIFICATION

(71) Applicant: DELL PRODUCTS L.P., Round Rock, TX (US)

(72) Inventors: Chun-Lin Liao, Taipei (TW); Chang-Hsien Chen, New Taipei City (TW); Jen-Hsiang Hsu, Beitou (TW); Bhyrav M. Mutnury, Round Rock, TX (US)

(21) Appl. No.: 18/765,438

(22) Filed: Jul. 8, 2024

(51) Int. Cl. H05K 1/02; G01R 31/28; H05K 1/11

(52) U.S. Cl. CPC H05K 1/0268; G01R 31/2812; H05K 1/115

(57) ABSTRACT

A printed circuit board, comprising a via configured to provide electrical connectivity between layers of the printed circuit board and having at least a portion of the via removed within a tolerance of a variable. The printer circuit board further includes a test coupon configured to detect a via stripping issue associated with the via, wherein the via stripping issue occurs when the portion of the via is removed outside of the tolerance of the variable.

### FIELD OF THE DISCLOSURE

The present disclosure generally relates to information handling systems, and more particularly relates to printed circuit board vendor backdrilling capability qualification.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

Information handling systems may include printed circuit boards (PCBs).

### SUMMARY

A printed circuit board, comprising a via configured to provide electrical connectivity between layers of the printed circuit board and having at least a portion of the via removed within a tolerance of a variable. The printer circuit board further includes a test coupon configured to detect a via stripping issue associated with the via, wherein the via stripping issue occurs when the portion of the via is removed outside of the tolerance of the variable.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIGS. 1A and 1B are block diagrams of an information handling system according to an embodiment of the present disclosure;

FIGS. 2-13 are cross-section views of printed circuit boards, according to an embodiment of the present disclosure;

FIG. 14 is a graph showing measurements performed by a vector network analyzer, according to an embodiment of the present disclosure;

FIG. 15 is a flowchart of a method for printed circuit board vendor backdrilling capability qualification, according to an embodiment of the present disclosure; and

FIG. 16 is a block diagram of an information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

Printed circuit boards (PCBs) are typically included with hardware components of an information handling system. PCBs may include multiple layers wherein along each layer, conductive members are routed. These conductive members are typically referred to as traces. Vias, that are disposed generally perpendicular to the PCB, are used to provide electrical connectivity between the traces on different layers of the PCB. The PCB may also include test coupons for evaluating PCB characteristics, as well as for quality control and operability. For example, the test coupons may be used to evaluate the backdrilling process of a PCB manufacturer, such as whether the PCB manufacturer is able to remove via stub properly. Accordingly, the present disclosure provides a system and method for printed circuit board vendor backdrilling capability qualification.

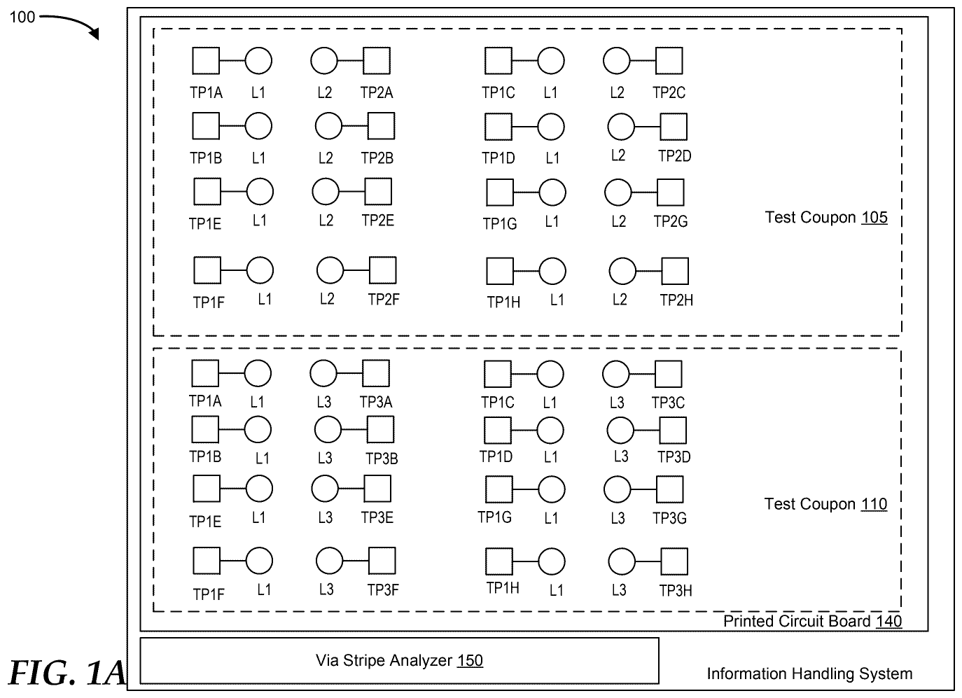

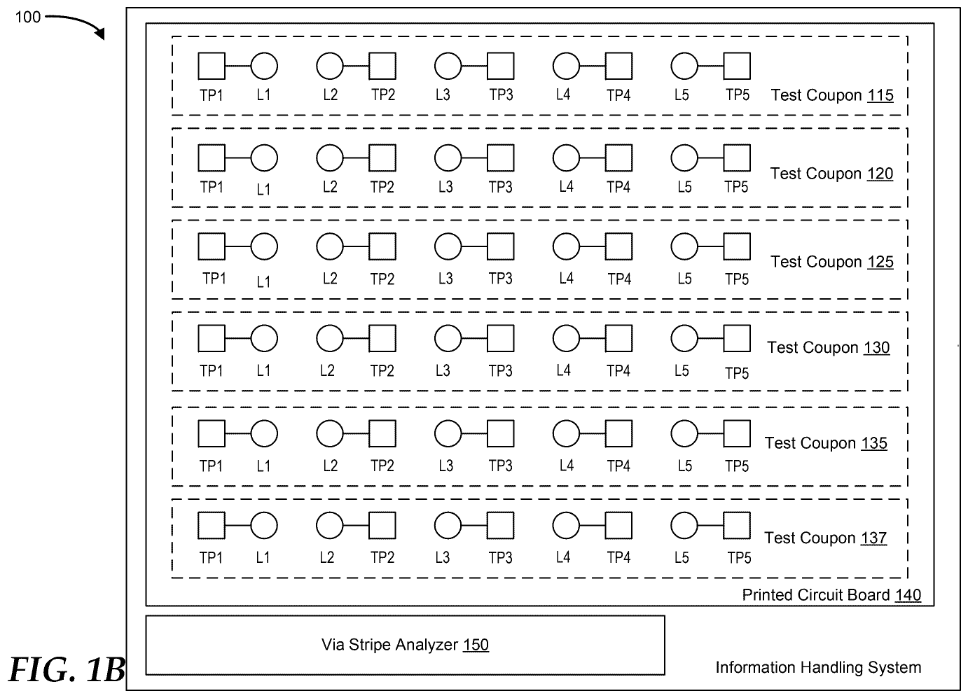

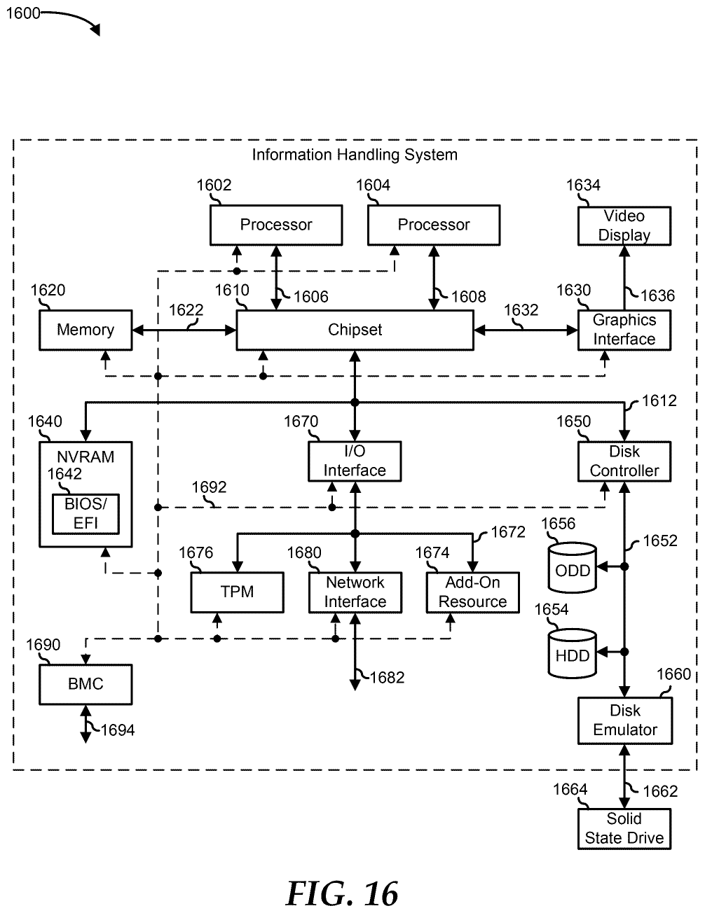

FIG. 1A shows a portion of an information handling system 100, such as information handling system 1600 of FIG. 16, according to an embodiment of the present disclosure. In this example, information handling system 100 includes a via stripe analyzer 150 and a PCB 140 that further includes test coupons 105 and 110. The test coupons may be disposed as shown along a portion of a PCB like PCB 140. However, the test coupons can be arranged differently than depicted. The test coupons may also be at a stand-alone PCB. Each one of the test coupons includes one or more test points. For example, test coupon 105 includes test points TP1, TP2, TP3, TP4, and TP5. The test points may be formed on a surface of PCB 140. In some embodiments, the test point may be plated with a conducting metal to provide a conductive connection.

The test points may be used to create an electrical contact between the test coupon and a test instrument, which may be used to test PCB 140 or a portion thereof. In one embodiment, the test point may be coupled with a subminiature version A (SMA) connector or a pad. The SMA connector or the pad may be coupled to a piece of testing equipment, such as a vector network analyzer (VNA), a time domain reflectometer (TDR), or similar. The VNA is a specialized piece of equipment configured to send test signals, such as sine waves to different frequencies, through the SMA connector.

One or more test coupons among test coupons 105 and 110 may be used to determine whether the PCB manufacturer meets qualification standards. Additional test coupons not shown may be used. For each one of test coupons 105 and 110, a test point along with another test point may be used to test different variables associated with a backdrill. In this example, test coupon 105 is used to test whether a backdrill is within a particular threshold for each variable based on a topmost metal layer and a second metal layer. Test coupon 110 is used to test whether the backdrill is within the particular threshold for each variable based on the topmost metal layer and a third metal layer. Other test coupons to detect via stripping and/or for backdrill variables may be used, wherein the test coupons may be associated with different combinations of test points than depicted herein.

A test point with a prefix TP1 is a test point for an associated trace on a top metal layer of PCB 140 that is connected to a test via (“L1”). The test via is a plated through-hole via that connects to traces on a second, third, fourth, and fifth metal layers of PCB 140. The traces on each lower metal layer are connected to secondary vias (labeled “L2” for the second metal layer, etc.). Each of the secondary vias is plated through-hole vias that connect the traces on the associated metal layers to the top metal layer. On the top metal layer, each of the secondary vias is connected by traces to their associated test point. For example, a test point with the prefix TP2 is a test point for an associated trace of PCB 140 that is connected to the test via L2. Each of the test coupons may be used to detect via striping and to narrow down a via stripe region. For example, if a potential via stripping is detected using test coupon 105, then the via stripping may be in the region between layer one and layer two.

The test coupons may be used to qualify PCB manufacturers, also referred to herein as PCB houses or PCB vendors, for potential via stripping issues before mass production of PCBs. In testing for potential via stripping issues, the test coupons may be used to test for backdrill variables, also referred to herein simply as variables, that can affect the possibility of via stripping and are not influenced by process variation, such as drilling size, drill misregistration, drilling angle or drill deflection, backdrill length, drill speed, drill bit size, etc. In particular, the test coupons may be used to test for corner cases or extreme cases associated with the different variables.

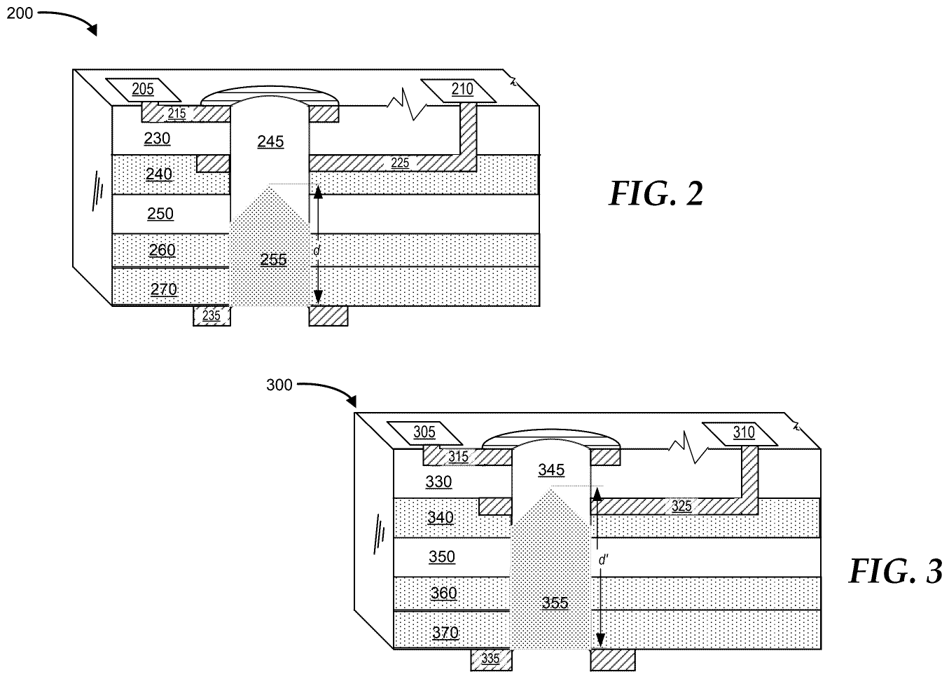

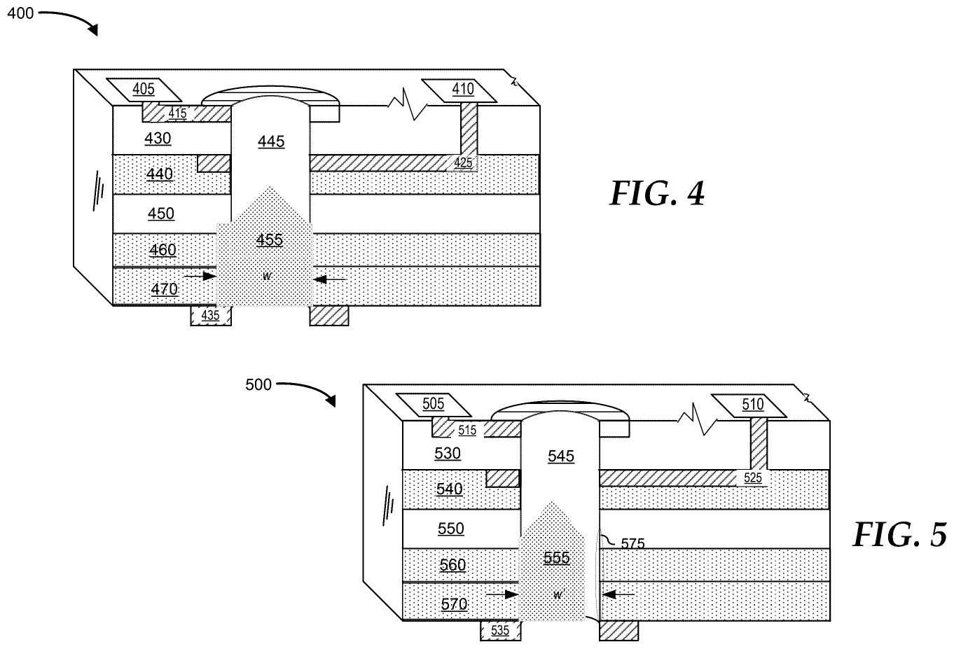

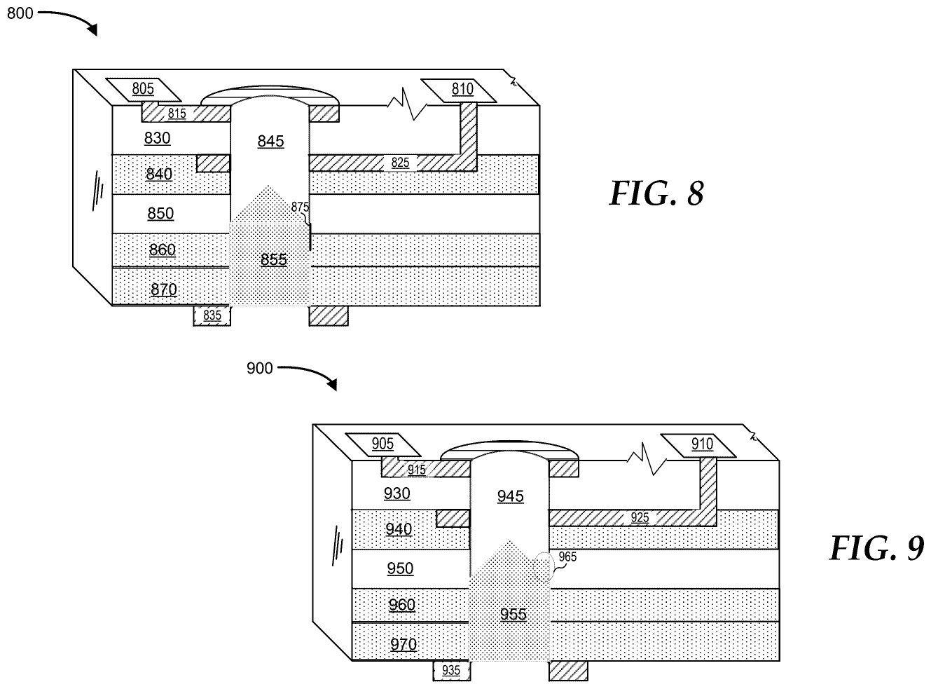

For example, test points TP1A with TP2A of test coupon 105 are used to test that a depth “d” or length of a backdrill 255 of FIG. 2 is within a minimum depth or length. Test points TP1B with TP2B in test coupon 105 are used to test that the depth “d′” or length of a backdrill 355 of FIG. 3 is within a maximum depth or length. Test points TP1C and TP2C of test coupon 105 are used to test that a width “w” of a backdrill 455 of FIG. 4 is within a maximum width or drill size. Test points TP1D and TP2D of test coupon 105 are used to test that the width “w′” of a backdrill 555 of FIG. 5 is within a minimum width or drill size. Test points TP1E and TP2E of test coupon 105 are used to test that a left skew of a backdrill 655 of FIG. 5 is within a maximum offset angle to the left. Test points TP1F and TP2F of test coupon 105 are used to test that a right skew of a backdrill 655 of FIG. 5 is within a maximum offset angle to the right. Test points TP1G and TP2G of test coupon 105 are used to test that a backdrill 855 of FIG. 8 is drilled within a minimum speed. Test points TP1H and TP2H of test coupon 105 are used to test that a backdrill 955 of FIG. 9 is drilled within a maximum speed.

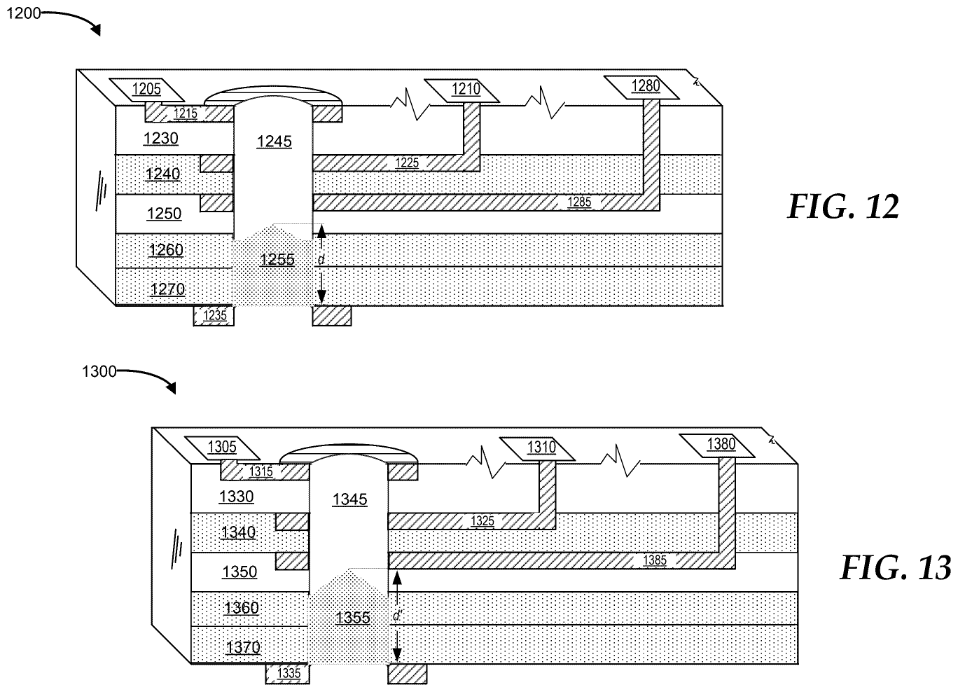

A trace on a third lower metal layer is connected to secondary vias (labeled “L3” for the third metal layer). A test point with a prefix TP3 is a test point for an associated trace of PCB 140 that is connected to test via L3. Similar to test coupon 105, test coupon 110 may be used to detect via striping and narrow down the via stripe region based on the test point associated with the top metal layer and the third metal layer. For example, test points TP1A with TP3A of test coupon 110 are used to test that a depth “d” or length of a backdrill 1255 of FIG. 12 is within a minimum depth or length. Test points TP1B with TP3B in test coupon 110 are used to test that the depth “d′” or length of a backdrill 1355 of FIG. 13 is within a maximum depth or length. Test points TP1C and TP3C of test coupon 110 are used to test that a width “w” of a backdrill is within a maximum width or drill size. Test points TP1D and TP3D of test coupon 110 are used to test the width “w′” of a backdrill within a minimum width or drill size. Test points TP1E and TP3E of test coupon 110 are used to test that a left skew of a backdrill is within a maximum offset angle to the left. Test points TP1F and TP3F of test coupon 110 are used to test that a right skew of a backdrill is within a maximum offset angle to the right. Test points TP1G and TP3G of test coupon 110 are used to test that a backdrill is drilled within a minimum speed. Test points TP1H and TP3H of test coupon 110 are used to test that a backdrill is drilled within a maximum speed.

Via stripe analyzer 150 may be configured to analyze insertion loss based on a measure of S parameters, such as S_{dd21} related to transmission properties. Via stripe analyzer 150 may compare current test results to measurements associated with baseline, extreme, and/or corner cases performed in a laboratory setting. For example, a PCB with vias that has no via stripping issues may be used as a baseline for insertion loss based on the S parameters if any. In another example, a PCB with vias that have via stripping issues within a pre-determined tolerance may be used to identify insertion loss for a corner case scenario. The current measurements may be compared with the measurements performed in the laboratory setting. Based on the comparison, via stripe analyzer 150 may determine or detect potential via stripping issues based on the presence of a resonance in the insertion loss. Via stripe analyzer 150 may provide a test report based on the aforementioned determination, wherein the test report may include a suggested set of actions to remedy the potential via stripping issues if possible. Via stripe analyzer 150 may also determine whether the PCB manufacturer passes or fails its qualification based on the test results.

Those of ordinary skill in the art will appreciate that the configuration of the test coupons and associated test points of PCB 140 depicted in FIG. 1 may vary. For example, the number of test coupons and test points are not intended to be exhaustive but rather are representative to highlight components that can be utilized to implement aspects of the present disclosure. For example, PCB 140 can have more or less than the test coupons shown. For example, PCB 140 may include test coupons that may include test points for the topmost layer and a secondary fourth layer. Although test coupons 105 and 110 may be configured to test a backdrill that is drilled from the bottom layer up and through one or more secondary layers, in another example, PCB 140 can include test coupons for testing for a backdrill that is drilled from the top most layer and down through one or more secondary layers. Further, each test coupon may have more or fewer test points than shown.

In addition, although there is a 1:1 association between a test point and a layer, the test coupon may not be configured as such. In addition, each layer of the PCB may not have an associated trace. Accordingly, although a test may be performed for each layer, a user may not have to do so. In addition, the test coupons may not test for each possible scenario, instead, the test coupons may test for the extreme or corner cases, which can cover scenarios in between. The depicted example does not convey or imply any architectural or other limitations with respect to the presently described embodiments and/or the general disclosure. In the discussion of the figures, reference may also be made to components illustrated in other figures for continuity of the description.

FIG. 1B shows a portion of an information handling system 100, such as information handling system 1600 of FIG. 16, according to an embodiment of the present disclosure. In this example, information handling system 100 includes via stripe analyzer 150 and a PCB 140 that further includes test coupons 115, 120, 125, 130, 135, and 137. Similar to test coupons 105 and 110, these test coupons may be disposed as shown along a portion of a PCB like PCB 140. However, each of test coupons 115, 120. 125, 130, 135, and 137 may be configured to test a particular backdrill variable. For example, test coupon 115 may be configured to test whether a backdrill meets a minimum tolerance for backdrill depth, such as backdrill 255 of FIG. 2. In this example, the test equipment may be coupled to test points TP1 and TP2, which is similar to test points 205 and 210 respectively of FIG. 2.

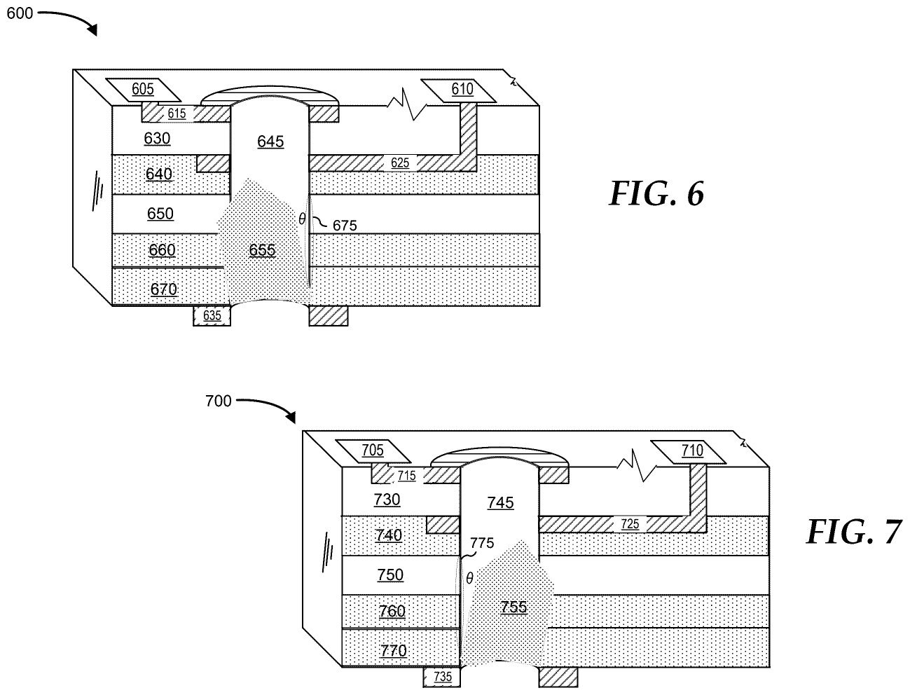

Test coupon 120 may be configured to test whether a backdrill, such as backdrill 355 of FIG. 3 meets maximum tolerance for backdrill depth, such as backdrill 355 of FIG. 3. In this example, the test equipment may be coupled to test points 305 and 310 of FIG. 3. Test coupon 125 may be configured to test whether a backdrill is, such as backdrill 455 of FIG. 4 meets maximum tolerance for backdrill width. Test coupon 130 may be configured to test whether a backdrill, such as backdrill 555 of FIG. 5 meets the minimum tolerance for backdrill width. Test coupon 135 may be configured to test whether a backdrill, such as backdrill 655 of FIG. 6 meets minimum or maximum left skew or angle deflation. Test coupon 137 may be configured to test whether a backdrill, such as backdrill 755 of FIG. 7 meets minimum or maximum right skew or angle deflation. PCB 140 may include additional test coupons to test other backdrill variables than depicted herein. Similar to FIG. 1A, the test coupons can be arranged differently than depicted. The test coupons may also be at a stand-alone PCB.

FIG. 2 shows a simplified cross-section of a portion of a PCB 200, which is similar to a portion of PCB 140 of FIG. 1A, according to an embodiment of the present disclosure. In particular, PCB 200 may be a portion of test coupon 105 of PCB 140 of FIG. 1A. PCB 200 includes layers 230, 240, 250, 260, and 270 and a via 245. In this example, test point 205 may correspond to TP1 of FIG. 1A while test point 210 may correspond to TP2 of FIG. 1A. Via 245 may correspond to via L1 of FIG. 1A. A via associated with L2 of FIG. 1A is not shown for simplicity. Layers 230 and 250 may be conducting layers, also referred to as signal layers, while layers 240, 260, and 270 may be isolating layers, also referred to as grounding layers which are formed from a resin with a relative permittivity that electrically isolates layers 230 and 250 from each other, as conducting and isolating layers may alternate.

Via 245 is a through hole via which is perpendicular to layers 230, 240, 250, 260, and 270. A wall of via 245 is plated with a conducting material often metallic, such as copper with desirable conductive properties, to form a conduction wall. Thus, via 245 may provide an electrical connection to layers 230 and 240. PCB 200 also includes traces 215, 225, and 235 and test points 205 and 210. Test point 205 is associated with trace 215 while test point 210 is associated with trace 225. Trace 215 may be associated with layer 230 while trace 225 may be associated with layer 240. Test points 205 and 210 may be located on the surface along a topmost layer, such as layer 230. Traces 215, 225, and 235 run parallel to the layers. In this example, via 245 can provide an electrical connection between traces 215 and 225.

The design of PCB 200 may result in an unused portion of via 245 due to the lack of required connectivity among layers 260 and 270. The unused portion of via 245 may be referred to as a via stub. Via stubs can cause impedance discontinuities and reflections that may have a negative effect on the performance of PCB 200. Negative effects include increased jitter, signal attenuation, as well as reduced noise margins. These unused portions may be removed by backdrilling with a mechanical drill bit thereby removing via material. Via 245 may have a defined backdrill depth in which it is desired to remove material from via 245, as depicted by backdrill 255. Backdrill 255 may be drilled to determine whether the PCB manufacturer can perform a backdrill within a minimum tolerance of a desired depth.

A predetermined backdrill depth would remove via material from the surface of PCB 200 and past each unused layer but not remove via material adjacent to a layer having a trace that requires electrical connectivity to the via. As a non-limiting example, if it is desired that via 245 provides connectivity between the traces of 215 and 225, the desired pre-determined depth of backdrill 255 would extend from the surface of the board past layer 260 but not past layer 240. In this example, a drill bit may have been used to drill through via 245 and remove the via material past through trace 235 and layers 260 and 270. However, it should be pointed out that the backdrilling can occur from the upper surface of PCB 200.

Due to the close tolerances of adjacent layers, the backdrilling process can remove excessive material than desired thereby opening a circuit designed to be closed. In other instances, the backdrilling process may result in a backdrill of an insufficient depth, wherein not enough via material is removed. This leaves at least a portion of the undesired via stub on the PCB. However, the backdrilling process may be performed with tolerances that provide some length of conduction wall stub. With regards to frequencies, the speed used during the backdrilling process may leave some via material than intended or remove more than the desired amount of via material. Tolerances may also be provided for how much of the via material can remain or how much in excess via material can be removed.

Previous PCB manufacturing techniques are not able to properly detect whether a backdrilled hole includes residual metal on the via. A current approach of micro-section analysis is used to detect the residual metal reactively after an interface fails during a debug phase of the PCB, which can damage the PCB. In addition, if the PCB is not cross sectioned at the right position, the via stripping issue may not be detected, because the cross-section may cut into the via stripping. Accordingly, it is desirable to detect via stripping without performing the micro-section analysis.

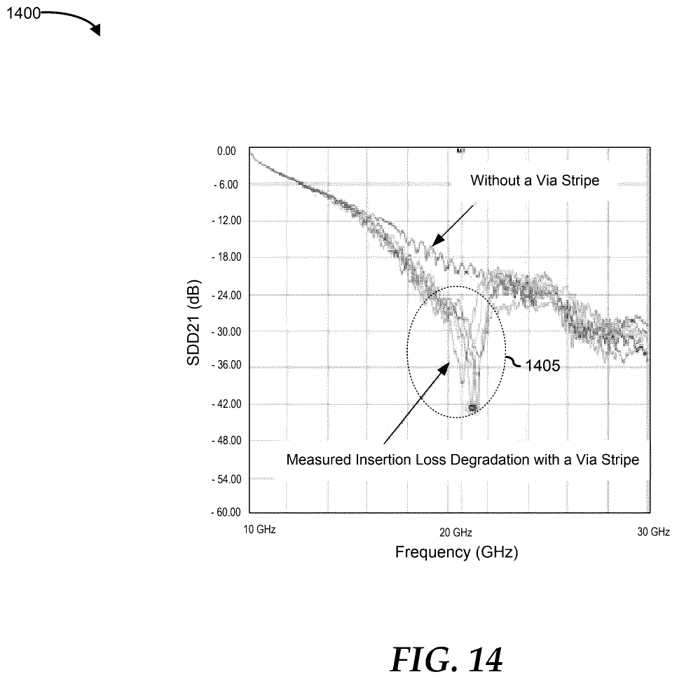

In one embodiment, test points 205 and/or 210 may be used to test variables associated with backdrill 255. For example, the testing may be used to confirm whether the vias of the board, such as via 245, has been backdrilled to the proper pre-determined depth. The confirmation may be in the form of electrical test results provided by the VNA measurements, such as shown in graph 1400 of FIG. 14. The VNA measurements may be performed to determine whether there is measured insertion loss degradation. Further, the VNA measurements may determine whether there is resonance in the insertion loss and/or whether the resonance exceeds a threshold. In a non-limiting example, if the resulting VNA measurements are within expected insertion loss degradation, then the backdrill may be within pre-determined tolerances associated with the variables, such as depth, misregistration, deflection, etc. The backdrill may also be within the pre-determined tolerances if no resonance of the insertion loss is determined.

In addition to the VNA, other test equipment, such as the TDR may be used to determine whether the depth of backdrill 255 is within a pre-determined tolerance of its desired backdrill depth based on other measurements, such as an impedance reading. For example, the VNA measurements and/or the impedance reading may determine if the depth “d” of backdrill 255 is within +−3 mils of the desired depth. If backdrill 255 is within the tolerance of the desired depth, then the test passes, and other tests may be performed to qualify the PCB manufacturer. If the test failed, then the PCB manufacturer may be notified, such that the manufacturer may improve their process.

Those of ordinary skill in the art will appreciate that the scenarios associated with variables that affect via stripping shown are representative and are used to highlight possible scenarios and the number of scenarios may vary. For example, variables that include depth, offset angle, speed, deflection, and misregistration are shown to provide possible scenarios and are non-limiting. Other scenarios associated with the aforementioned variables and other variables are possible. In addition, the number of test coupons and test points are not intended to be exhaustive but rather are representative to highlight components that can be utilized to implement aspects of the present disclosure. One of skill in the art will appreciate that PCB 200 may have a various number of traces and test points than shown herein. Although not all of the traces and/or layer shown herein has an associated test point, one of skill in the art will appreciate that the diagram explains a typical example, which can be extended in practice.

FIG. 3 shows a simplified diagram of a cross-section of a portion of a PCB 300, according to an embodiment of the present disclosure. PCB 300 is similar to PCB 200 of FIG. 2. In particular, layers 330, 340, 350, 360, and 370 are similar to layers 230, 240, 250, 260, and 270 of FIG. 2. In addition, test points 305 and 310 are similar to test points 205 and 210 of FIG. 2. Also, via 345 is similar to via 245 of FIG. 2 while backdrill 355 is similar to backdrill 255. Backdrill 355 may be drilled to determine whether the PCB manufacturer can drill a backdrill within a maximum tolerance of a desired depth. Further, traces 315, 325, and 335 are similar to traces 215, 225, and 235 of FIG. 2. Similar to FIG. 2, a via corresponding to via L2 of FIG. 1A is not shown for simplicity.

However, in this example, the drill bit drilled through layers 370, 360, and 350, as depicted by backdrill 355. Further, the depth of backdrill 355 as depicted in depth “d” may be deeper than backdrill 255. Similar to PCB 200 of FIG. 2, test points 305 and 310 may be coupled to a test equipment, such as a VNA and/or TDR for testing the variables associated with backdrill 355. For example, the testing may be used to confirm whether the vias of the board, such as via 245, has been backdrilled to the proper pre-determined depth.

FIG. 4 shows a simplified diagram of a cross-section of a portion of a PCB 400, according to an embodiment of the present disclosure. PCB 400 may be similar to PCB 200 of FIG. 2. In particular, layers 430, 440, 450, 460, and 470 are similar to layers 230, 240, 250, 260, and 270 of FIG. 2. In addition, test points 405 and 410 are similar to test points 205 and 210 of FIG. 2. Also, via 445 is similar to via 245 of FIG. 2 while a backdrill 455 is similar to backdrill 255 of FIG. 2. Further, traces 415, 425, and 435 are similar to traces 215, 225, and 235 of FIG. 2. Backdrill 455 may be drilled to determine whether the PCB manufacturer can perform a backdrill within a maximum tolerance of a desired width.

However, in this example, the drill bit used for backdrill 455 may be of a different size than desired. As such, the width ‘w’ of backdrill 455 may be wider than the desired diameter. Typically, the via diameter may be similar to the backdrill diameter. In certain situations, the backdrill diameter of the backdrill may be greater than the via diameter within a certain tolerance. In addition, a tolerance for drill bit size may be provided. Similar to PCB 200 of FIG. 2, test points 405 and 410 may be coupled to a VNA and/or TDR for testing variables associated with backdrill 455. For example, the testing may be used to confirm whether the backdrill 455 is within the pre-determined tolerances for backdrill width. For example, the VNA measurements and/or the impedance reading may determine if backdrill 455 is within +−3 mils of the desired width. If backdrill 455 is within the tolerance of the desired width, then the test passes, and/or other tests may be performed to qualify the PCB manufacturer. If the test failed, then the PCB manufacturer may be notified, such that the manufacturer may improve their process.

FIG. 5 shows a simplified diagram of a cross-section of a portion of a PCB 500, according to an embodiment of the present disclosure. PCB 500 may be similar to PCB 400 of FIG. 4. In particular, layers 530, 540, 550, 560, and 570 are similar to layers 430, 440, 450, 460, and 470 of FIG. 4. In addition, test points 505 and 510 are similar to test points 405 and 410 of FIG. 4. Also, via 545 is similar to via 445 of FIG. 4 while a backdrill 555 is similar to backdrill 455 of FIG. 4. Backdrill 555 may be drilled to determine whether the PCB manufacturer can perform a backdrill within a minimum tolerance of a desired width. Further, traces 515, 525, and 535 are similar to traces 415, 425, and 435 of FIG. 4.

However, in this example, the width “w” of backdrill 455 may be narrower than the desired diameter. Similar to PCB 400 of FIG. 4, test points 505 and 510 may be coupled to a VNA and/or TDR for testing variables associated with backdrill 555. For example, the testing may be used to confirm whether the backdrill 555 is within the pre-determined tolerances for backdrill width. For example, the VNA measurements and/or the impedance reading may determine if backdrill 555 is within +−3 mils of the desired drill width or drill bit size. In addition, the testing may be used to determine whether a potential via striping, such as residual via material 575 is present and determine its location. If backdrill 555 is within the tolerance of the desired drill registration, then the test passes, and/or other tests may be performed to qualify the PCB manufacturer. If the test failed, then the PCB manufacturer may be notified, such that the manufacturer may improve their process.

FIG. 6 shows a simplified diagram of a cross-section of a portion of a PCB 600, according to an embodiment of the present disclosure. PCB 600 may be similar to PCB 200 of FIG. 2. In particular, layers 630, 640, 650, 660, and 670 are similar to layers 230, 240, 250, 260, and 270 of FIG. 2. In addition, test points 605 and 610 are similar to test points 205 and 210 of FIG. 2. Also, via 645 is similar to via 245 of FIG. 2 while a backdrill 655 is similar to backdrill 255 of FIG. 2. Backdrill 655 may be drilled to determine whether the PCB manufacturer can perform a backdrill within a minimum or maximum tolerance of a desired right-side offset angle. Further, traces 615, 625, and 635 are similar to traces 215, 225, and 235 of FIG. 2.

However, in this example, the drilling angle of the drill bit may be misaligned. In particular, the angle backdrill 655 may be offset, such as backdrill 655 may be drilled off center by an offset angle that is substantially equal to theta “0.” Typically, backdrill 655 may be drilled based on the center of via 645. Because of the offset angle, the backdrilling may not remove all of the desired via material, such that a residual amount of via material may remain, as depicted in residual via material 675. The residual via material from backdrilling may be a potential via stripping issue. Accordingly, residual via material 675 may act as an additional length to via stub of via 645. This may impact signal integrity and impedance for high-speed signals traveling along via 645.

In certain situations, the backdrill angle may be greater than or less than the desired angle. However, a tolerance for the drill deflection may be provided. Similar to PCB 200 of FIG. 2, test points 605 and 610 may be coupled to a VNA and/or TDR for testing variables associated with backdrill 655. For example, the testing may be used to confirm whether the backdrill 455 is within the pre-determined tolerances for backdrill deflection. In particular, the VNA measurements and/or the impedance reading may determine if angle θ of backdrill 455 is within the tolerance of the desired deflection. If backdrill 455 is within the tolerance of the desired drill deflection, then the test passes, and other tests may be performed to qualify the PCB manufacturer. If the test failed, then the PCB manufacturer may be notified, such that the manufacturer may improve their process.

FIG. 7 shows a simplified diagram of a cross-section of a portion of a PCB 700, according to an embodiment of the present disclosure. PCB 700 may be similar to PCB 600 of FIG. 6. In particular, layers 730, 740, 750, 760, and 770 are similar to layers 630, 640, 650, 660, and 670 of FIG. 6. In addition, test points 705 and 710 are similar to test points 605 and 610 of FIG. 6. Also, via 745 is similar to via 645 of FIG. 6 while a backdrill 755 is similar to backdrill 655 of FIG. 6. Backdrill 655 may be drilled to determine whether the PCB manufacturer can perform a backdrill within a minimum or maximum tolerance of a desired left-side offset angle. Further, traces 715, 725, and 735 are similar to traces 615, 625, and 635 of FIG. 6.

However, in this example, backdrill 755 may have a drill deflection angle of “0” at another side of via 745, which may result in a residual via material 775. Similar to PCB 600 of FIG. 6, test points 705 and 710 may be coupled to a VNA and/or TDR for testing variables associated with backdrill 755. For example, the testing may be used to confirm whether the backdrill 755 is within the pre-determined tolerances for the backdrill deflection angle.

FIG. 8 shows a simplified diagram of a cross-section of a portion of a PCB 800, according to an embodiment of the present disclosure. PCB 800 may be similar to PCB 200 of FIG. 2. In particular, layers 830, 840, 850, 860, and 870 are similar to layers 230, 240, 250, 260, and 270 of FIG. 2. In addition, test points 805 and 810 are similar to test points 205 and 210 of FIG. 2. Also, via 845 is similar to via 245 of FIG. 2 while a backdrill 855 is similar to backdrill 255 of FIG. 2. Backdrill 855 may be drilled to determine whether the PCB manufacturer can drill a backdrill within a minimum tolerance of a desired speed. Further, traces 815, 825, and 835 are similar to traces 215, 225, and 235 of FIG. 2.

In certain situations, the speed of the drill bit used for the backdrill may be greater than or less than the desired speed. However, a tolerance for the drill bit speed may be provided. In one example, if the speed of the drill bit is less than the desired speed, then the backdrilling may not remove all of the desired via material, such that some via material may be left, as depicted in a residual via material 875. Accordingly, residual via material 875 may act as an additional length to via stub of via 845. This may impact signal integrity and impedance for high-speed signals traveling along via 845.

Similar to PCB 200 of FIG. 2, test points 805 and 810 may be coupled to a VNA and/or TDR for testing variables associated with backdrill 855. For example, the testing may be used to confirm whether there are via materials left around backdrill 855, such as residual via material 875. For example, the VNA measurements and/or the impedance reading may determine if the amount of residual via material around backdrill 855 is within the tolerance. If the speed of backdrill 455 is within the tolerance of the desired drill registration based on the amount of residual via material, then the test passes, and other tests may be performed to qualify the PCB manufacturer. If the test failed, then the PCB manufacturer may be notified, such that the manufacturer may improve their process.

FIG. 9 shows a simplified diagram of a cross-section of a portion of a PCB 900, according to an embodiment of the present disclosure. PCB 900 may be similar to PCB 800 of FIG. 8. In particular, layers 930, 940, 950, 960, and 970 are similar to layers 830, 840, 850, 860, and 870 of FIG. 8. In addition, test points 905 and 910 are similar to test points 805 and 810 of FIG. 8. Also, via 945 is similar to via 845 of FIG. 8 while a backdrill 955 is similar to backdrill 855 of FIG. 8. Backdrill 855 may be drilled to determine whether the PCB manufacturer can drill a backdrill within a maximum tolerance of a desired speed. Further, traces 915, 925, and 935 are similar to traces 815, 825, and 835 of FIG. 8.

However, in this example, the speed of the drill bit used for backdrill 955 may be faster than the desired speed which can result in removing more via material than desired, such as depicted in additional backdrill area 965. Similar to PCB 800 of FIG. 8, test points 905 and 910 may be coupled to a VNA and/or TDR for testing variables associated with backdrill 955. For example, the testing may be used to confirm whether the speed of the drill bit used for backdrill 955 is within the pre-determined tolerances based on the area of backdrill 955.

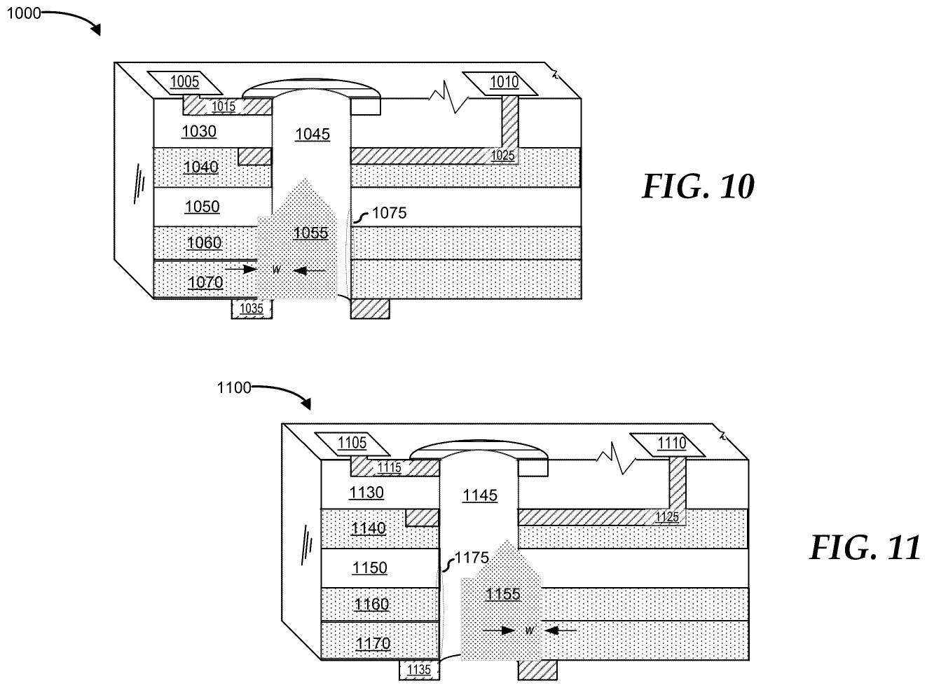

FIG. 10 shows a simplified diagram of a cross-section of a portion of a PCB 1000, according to an embodiment of the present disclosure. PCB 1000 may be similar to PCB 200 of FIG. 2. In particular, layers 1030, 1040, 1050, 1060, and 1070 are similar to layers 230, 240, 250, 260, and 270 of FIG. 2. In addition, test points 1005 and 1010 are similar to test points 205 and 210 of FIG. 2. Also, via 1045 is similar to via 245 of FIG. 2 while a backdrill 455 is similar to backdrill 255 of FIG. 2. Further, traces 1015, 1025, and 1035 are similar to traces 215, 225, and 235 of FIG. 2. Backdrill 455 may be drilled to determine whether the PCB manufacturer can perform a backdrill within a misregistration tolerance, wherein a portion of via 1045 to the right may be exposed.

In this example, the backdrill may be misregistered to the left by width “w” resulting in an exposed via material 1075. A minimum and/or maximum tolerance for drill misregistration may be provided. Similar to PCB 200 of FIG. 2, test points 1005 and 1010 may be coupled to a VNA and/or TDR for testing variables associated with backdrill 1055. For example, the testing may be used to confirm whether backdrill 1055 is within the pre-determined tolerances for backdrill misregistration. For example, the VNA measurements and/or the impedance reading may determine if backdrill 455 is within +−3 mils of the desired tolerance for misregistration. If backdrill 455 is within the tolerance of the desired misregistration, then the test passes, and/or other tests may be performed to qualify the PCB manufacturer. If the test failed, then the PCB manufacturer may be notified, such that the manufacturer may improve their process.

FIG. 11 shows a simplified diagram of a cross-section of a portion of a PCB 1100, according to an embodiment of the present disclosure. PCB 1100 may be similar to PCB 1000 of FIG. 10. In particular, layers 1130, 1140, 1150, 1160, and 1170 are similar to layers 1030, 1040, 1050, 1060, and 1070 of FIG. 4. In addition, test points 1105 and 1110 are similar to test points 1005 and 1010 of FIG. 10. Also, via 1145 is similar to via 1045 of FIG. 10 while a backdrill 1155 is similar to backdrill 1055 of FIG. 10. Backdrill 1155 may be drilled to determine whether the PCB manufacturer can perform a backdrill within a minimum tolerance of a desired width. Further, traces 1115, 1125, and 1135 are similar to traces 1015, 1025, and 1035 of FIG. 10.

In this example, the backdrill may be misregistered to the right by width “w′” resulting in an exposed via material 1175. For example, the VNA measurements and/or the impedance reading may determine if backdrill 1155 is within +−3 mils of the desired tolerance for misregistration. If backdrill 1155 is within the tolerance of the desired misregistration, then the test passes, and/or other tests may be performed to qualify the PCB manufacturer. If the test failed, then the PCB manufacturer may be notified, such that the manufacturer may improve their process.

FIG. 12 shows a simplified cross-section of a portion of a PCB 1200, which is similar to a portion of PCB 140 of FIG. 1A, according to an embodiment of the present disclosure. In particular, PCB 1200 may be a portion of test coupon 110 of PCB 140 of FIG. 1A. PCB 1200 may be similar to PCB 200 of FIG. 2. In particular, layers 1230, 1240, 1250, 1260, and 1270 are similar to layers 230, 240, 250, 260, and 270 of FIG. 2. In addition, test points 1205 and 1210 are similar to test points 205 and 210 of FIG. 2. PCB 1200 also includes test point 1280 which may correspond to test points of the prefix TP3 of FIG. 1A. A via associated with L3 of FIG. 1A is not shown for simplicity. Via 1245 is similar to via 245 of FIG. 2 while backdrill 1255 of depth “d” is similar to backdrill 255 of FIG. 2. Further, traces 1215, 1225, and 435 are similar to traces 215, 225, and 235 of FIG. 2. In addition, PCB 1200 also includes a trace 1285 that is associated with test point 1280. Backdrill 1255 may be drilled to determine whether the PCB manufacturer can perform a backdrill within a maximum tolerance of a desired width.

In one embodiment, similar to test points 205 and 210 of FIG. 2, test points 1205 and/or 1280 may be used to test variables associated with backdrill 1255 by connecting the aforementioned test points to a test equipment. The VNA measurements provided by the test equipment may determine whether there is resonance in the insertion loss. In a non-limiting example, if the resulting VNA measurements are within expected insertion loss degradation, then the backdrill may be within pre-determined tolerances associated with the variables, such as depth, misregistration, deflection, etc. The backdrill may also be within the pre-determined tolerances if no resonance of the insertion loss is determined.

FIG. 13 shows a simplified diagram of a cross-section of a portion of a PCB 1300, according to an embodiment of the present disclosure. PCB 1300 is similar to PCB 1200 of FIG. 12. In particular, layers 1330, 1340, 1350, 1360, and 1370 are similar to layers 1230, 1240, 1250, 1260, and 1270 of FIG. 12. In addition, test points 1305, 1310, and 1380 are similar to test points 1205, 1210, and 1280 of FIG. 12. Also, via 1345 is similar to via 1245 of FIG. 12 while backdrill 1355 is similar to backdrill 1255 of FIG. 12. Backdrill 1355 may be drilled to determine whether the PCB manufacturer can drill a backdrill within a maximum tolerance of a desired depth. Further, traces 1315, 1325, 1335, and 1385 are similar to traces 1215, 1225, 1235, and 1285 of FIG. 12. Similar to FIG. 12, a via corresponding to via L2 of FIG. 1A is not shown for simplicity.

In this example, the drill bit drilled through layers 1370 and 1360, as depicted by backdrill 1355. Further, the depth of backdrill 1355 as depicted in depth “d′” may be deeper than depth “d” of backdrill 1255. Similar to PCB 1200 of FIG. 12, test points 1305 and 1380 may be coupled to a test equipment, such as a VNA and/or TDR for testing the variables associated with backdrill 1355. For example, the testing may be used to confirm whether the vias of the board, such as via 1345 have been backdrilled to the proper pre-determined depth.

FIG. 14 shows a graph 1400 of a measurement of insertion loss degradation, according to an embodiment of the present disclosure. Graph 1400 shows values of a Scattering parameter (S-parameter) transmission factor, forward differential insertion loss (SDD21) in a vertical axis in decibels (dB) versus frequency in hertz (Hz) or gigahertz (GHz) of a radio frequency wave in a horizontal axis as measured using a VNA. The SDD21 represents a ratio of the output voltage to the input voltage. Insertion loss measurement may be used to analyze transmission feed line installation and performance quality. An increase in an insertion loss may correspond to a loss of coverage and may indicate a via stripe. Graph 1400 shows a resonance in the insertion loss possibly due to a potential via stripping issue, as indicated in section 1405. In one embodiment, a user may visually analyze the measurements provided by the VNA. In another embodiment, a via stripe analyzer may analyze the measurements and determine whether there is a resonance in the insertion loss.

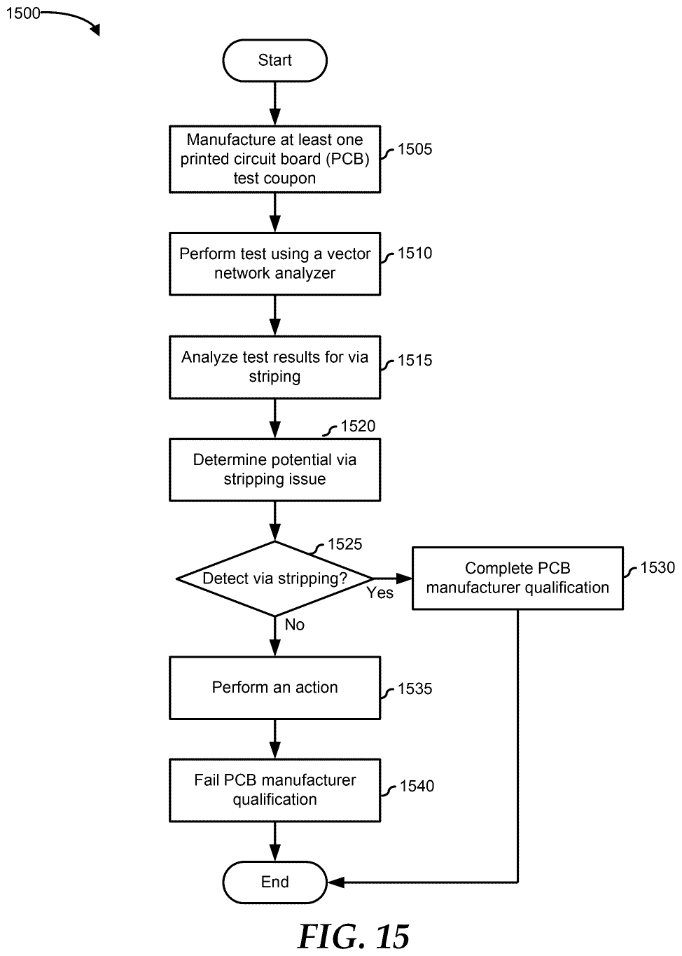

FIG. 15 shows a flowchart of a method 1500 for PCB vendor backdrilling capability qualification. Method 1500 may be performed by any suitable component including, but not limited to information handling system 1600 of FIG. 16. While embodiments of the present disclosure are described in terms of the components of information handling system 1600 of FIG. 16, it should be recognized that other components may be utilized to perform the described method. One of skill in the art will appreciate that this sequence diagram explains a typical example, which can be extended to applications or services in practice. In addition, it will be readily appreciated that not every method step set forth in this flow diagram is always necessary and that certain steps of the methods may be combined, performed simultaneously, in a different order, or perhaps omitted, without varying from the scope of the disclosure.

At block 1505, a PCB manufacture with test coupons is completed. For example, the PCB may include any state of the PCB, such as before components are added to the surface of the PCB. For example, the PCB may include multiple layers, wherein conducting layers may be separated by insulating layers. The PCB may also include one or more vias and the via may result in a via stub. The via stub may impact the signal integrity of high-speed signal within the PCB. As such, the PCB may include one or more backdrilled holes to remove extra metal from the via. For example, a goal of a backdrill operation may be to only leave a stub that is within a particular tolerance for PCIe interfaces.

At block 1510, a test may be performed via the test coupons to detect via stripping based on measured insertion loss degradation. In an example, a VNA may be coupled to one or more test points in each of the test coupons and utilized to detect via stripes. The test may also be performed using at least one of the test coupons. Test results that include information similar to graph 1400 may be provided by the VNA. At block 1515, a via stripe analyzer may be used to analyze the test results to detect via stripping. The via stripe analyzer may compare current measurements to measurements performed at a laboratory setting to determine if there is a resonance in the insertion loss to qualify PCB manufacturers, also referred to as PCB houses. If there is resonance in the insertion loss, there is potentially a via stripping issue. The via stripe analyzer may determine if insertion loss degradation is greater than a threshold and/or associated with a via stripe. In particular, if the insertion loss is above or below a threshold value, then a potential via stripping issue is determined at block 1520.

At decision block 1525, if a via stripping is detected, then the “YES” branch is taken, and the method proceeds to block 1530. If a via striping is not detected, then the “NO” branch is taken, and the method proceeds to block 1535. At block 1530, the PCB verification and PCB manufacturer qualification are complete and then the method ends. The PCB manufacturer may be qualified if there is no potential via stripes detected during the test process. The PCB manufacturer may also be qualified if the PCB manufacturer meets a threshold for the number of potential via stripes. When the PCB manufacturer is qualified then the PCB manufacturer may continue with manufacturing PCBs. At block 1535, one or more actions, such as identifying location and/or fixing the via stripe. In addition, the action may include providing a notification to a user, providing information associated with the via striping issue in a test report, or storing the information in a memory. The test report may include a list of actions to correct a potential via stripping issue. At block 1540, the method may fail the test and withhold PCB manufacturer qualification afterward the method ends.

While FIGS. 2-13 show a simplified PCB board, it should be understood that modern PCBs often have more layers and both the front and back sides of the PCB may be used for mounting components. Thus, one or more connection holes on both the front and back of the PCB may be backdrilled before mounting components, depending on whether the component is to be mounted on the front or back of the PCB. In addition, a few examples are shown in FIGS. 2-13, those skilled in the art will readily appreciate that many modifications in the exemplary embodiments may be performed without limiting the present disclosure.

FIG. 16 illustrates an embodiment of an information handling system 1600 including processors 1602 and 1604, a chipset 1610, a memory 1620, a graphics adapter 1630 connected to a video display 1634, a non-volatile RAM (NVRAM) 1640 that includes a basic input and output system/extensible firmware interface (BIOS/EFI) module 1642, a disk controller 1650, a hard disk drive (HDD) 1654, an optical disk drive 1656, a disk emulator 1660 connected to a solid-state drive (SSD) 1664, an input/output (I/O) interface 1670 connected to an add-on resource 1674 and a trusted platform module (TPM) 1676, a network interface 1680, and a baseboard management controller (BMC) 1690. Processor 1602 is connected to chipset 1610 via processor interface 1606, and processor 1604 is connected to the chipset via processor interface 1608. In a particular embodiment, processors 1602 and 1604 are connected together via a high-capacity coherent fabric, such as a HyperTransport link, a QuickPath Interconnect, or the like. Chipset 1610 represents an integrated circuit or group of integrated circuits that manages the data flow between processors 1602 and 1604 and the other elements of information handling system 1600. In a particular embodiment, chipset 1610 represents a pair of integrated circuits, such as a northbridge component and a southbridge component. In another embodiment, some or all of the functions and features of chipset 1610 are integrated with one or more of processors 1602 and 1604.

Memory 1620 is connected to chipset 1610 via a memory interface 1622. An example of memory interface 1622 includes a Double Data Rate (DDR) memory channel and memory 1620 represents one or more DDR Dual In-Line Memory Modules (DIMMs). In a particular embodiment, memory interface 1622 represents two or more DDR channels. In another embodiment, one or more of processors 1602 and 1604 include a memory interface that provides a dedicated memory for the processors. A DDR channel and the connected DDR DIMMs can be in accordance with a particular DDR standard, such as a DDR3 standard, a DDR4 standard, a DDR5 standard, or the like.

Memory 1620 may further represent various combinations of memory types, such as Dynamic Random Access Memory (DRAM) DIMMs, Static Random Access Memory (SRAM) DIMMs, non-volatile DIMMs (NV-DIMMs), storage class memory devices, Read-Only Memory (ROM) devices, or the like. Graphics adapter 1630 is connected to chipset 1610 via a graphics interface 1632 and provides a video display output 1636 to a video display 1634. An example of a graphics interface 1632 includes a Peripheral Component Interconnect-Express (PCIe) interface and graphics adapter 1630 can include a four-lane (x4) PCIe adapter, an eight-lane (x8) PCIe adapter, a 16-lane (x16) PCIe adapter, or another configuration, as needed or desired. In a particular embodiment, graphics adapter 1630 is provided down on a system printed circuit board (PCB). Video display output 1636 can include a Digital Video Interface (DVI), a High-Definition Multimedia Interface (HDMI), a DisplayPort interface, or the like, and video display 1634 can include a monitor, a smart television, an embedded display such as a laptop computer display, or the like.

NVRAM 1640, disk controller 1650, and I/O interface 1670 are connected to chipset 1610 via an I/O channel 1612. An example of I/O channel 1612 includes one or more point-to-point PCIe links between chipset 1610 and each of NVRAM 1240, disk controller 1650, and I/O interface 1670. Chipset 1610 can also include one or more other I/O interfaces, including a PCIe interface, an Industry Standard Architecture (ISA) interface, a Small Computer Serial Interface (SCSI) interface, an Inter-Integrated Circuit (I²C) interface, a System Packet Interface, a Universal Serial Bus (USB), another interface, or a combination thereof. NVRAM 1640 includes BIOS/EFI module 1642 that stores machine-executable code (BIOS/EFI code) that operates to detect the resources of information handling system 1600, to provide drivers for the resources, to initialize the resources, and to provide common access mechanisms for the resources. The functions and features of BIOS/EFI module 1642 will be further described below.

Disk controller 1650 includes a disk interface 1652 that connects the disc controller to a hard disk drive (HDD) 1654, to an optical disk drive (ODD) 1656, and to disk emulator 1660. An example of disk interface 1652 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 1660 permits SSD 1664 to be connected to information handling system 1600 via an external interface 1662. An example of external interface 1662 includes a USB interface, an institute of electrical and electronics engineers (IEEE) 1394 (Firewire) interface, a proprietary interface, or a combination thereof. Alternatively, SSD 1664 can be disposed within information handling system 1600.

I/O interface 1670 includes a peripheral interface 1672 that connects the I/O interface to add-on resource 1674, to TPM 1676, and to network interface 1680. Peripheral interface 1672 can be the same type of interface as I/O channel 1612 or can be a different type of interface. As such, I/O interface 1670 extends the capacity of I/O channel 1612 when peripheral interface 1672 and the I/O channel are of the same type, and the I/O interface translates information from a format suitable to the I/O channel to a format suitable to the peripheral interface 1672 when they are of a different type. Add-on resource 1674 can include a data storage system, an additional graphics interface, a network interface card (NIC), a sound/video processing card, another add-on resource, or a combination thereof. Add-on resource 1674 can be on a main circuit board, on separate circuit board, or add-in card disposed within information handling system 1600, a device that is external to the information handling system, or a combination thereof.

Network interface 1680 represents a network communication device disposed within information handling system 1600, on a main circuit board of the information handling system, integrated onto another component such as chipset 1610, in another suitable location, or a combination thereof. Network interface 1680 includes a network channel 1682 that provides an interface to devices that are external to information handling system 1600. In a particular embodiment, network channel 1682 is of a different type than peripheral interface 1672 and network interface 1680 translates information from a format suitable to the peripheral channel to a format suitable to external devices.

In a particular embodiment, network interface 1680 includes a NIC or host bus adapter (HBA), and an example of network channel 1682 includes an InfiniBand channel, a Fibre Channel, a Gigabit Ethernet channel, a proprietary channel architecture, or a combination thereof. In another embodiment, network interface 1680 includes a wireless communication interface, and network channel 1682 includes a Wi-Fi channel, a near-field communication (NFC) channel, a Bluetooth® or Bluetooth-Low-Energy (BLE) channel, a cellular based interface such as a Global System for Mobile (GSM) interface, a Code-Division Multiple Access (CDMA) interface, a Universal Mobile Telecommunications System (UMTS) interface, a Long-Term Evolution (LTE) interface, or another cellular based interface, or a combination thereof. Network channel 1682 can be connected to an external network resource (not illustrated). The network resource can include another information handling system, a data storage system, another network, a grid management system, another suitable resource, or a combination thereof.

BMC 1690 is connected to multiple elements of information handling system 1600 via one or more management interface 1692 to provide out of band monitoring, maintenance, and control of the elements of the information handling system. As such, BMC 1690 represents a processing device different from processor 1602 and processor 1604, which provides various management functions for information handling system 1600 of FIG. 16. For example, BMC 1690 may be responsible for power management, cooling management, and the like. The term BMC is often used in the context of server systems, while in a consumer-level device, a BMC may be referred to as an embedded controller (EC). A BMC included in a data storage system can be referred to as a storage enclosure processor. A BMC included at a chassis of a blade server can be referred to as a chassis management controller and embedded controllers included at the blades of the blade server can be referred to as blade management controllers. Capabilities and functions provided by BMC 1690 can vary considerably based on the type of information handling system. BMC 1690 can operate in accordance with an Intelligent Platform Management Interface (IPMI). Examples of BMC 1690 include an Integrated Dell® Remote Access Controller (iDRAC).

Management interface 1692 represents one or more out-of-band communication interfaces between BMC 1690 and the elements of information handling system 1600 and can include an Inter-Integrated Circuit (I²C) bus, a System Management Bus (SMBUS), a Power Management Bus (PMBUS), a Low Pin Count (LPC) interface, a serial bus such as a Universal Serial Bus (USB) or a Serial Peripheral Interface (SPI), a network interface such as an Ethernet interface, a high-speed serial data link such as a PCIe interface, a Network Controller Sideband Interface (NC-SI), or the like. As used herein, out-of-band access refers to operations performed apart from a BIOS/operating system execution environment on information handling system 1600, that is apart from the execution of code by processors 1602 and 1604 and procedures that are implemented on the information handling system in response to the executed code.

BMC 1690 operates to monitor and maintain system firmware, such as code stored in BIOS/EFI module 1642, option ROMs for graphics adapter 1630, disk controller 1650, add-on resource 1674, network interface 1680, or other elements of information handling system 1600, as needed or desired. In particular, BMC 1690 includes a network interface 1694 that can be connected to a remote management system to receive firmware updates, as needed or desired. Here, BMC 1690 receives the firmware updates, stores the updates to a data storage device associated with the BMC, and transfers the firmware updates to the NVRAM of the device or system that is the subject of the firmware update, thereby replacing the currently operating firmware associated with the device or system, and reboots information handling system, whereupon the device or system utilizes the updated firmware image.

BMC 1690 utilizes various protocols and application programming interfaces (APIs) to direct and control the processes for monitoring and maintaining the system firmware. An example of a protocol or API for monitoring and maintaining the system firmware includes a graphical user interface (GUI) associated with BMC 1690, an interface defined by the Distributed Management Taskforce (DMTF) (such as a Web Services Management (WSMan) interface, a Management Component Transport Protocol (MCTP) or, a Redfish® interface), various vendor defined interfaces (such as a Dell EMC Remote Access Controller Administrator (RACADM) utility, a Dell EMC OpenManage Enterprise, a Dell EMC OpenManage Server Administrator (OMSA) utility, a Dell EMC OpenManage Storage Services (OMSS) utility, or a Dell EMC OpenManage Deployment Toolkit (DTK) suite), a BIOS setup utility such as invoked by a “F2” boot option, or another protocol or API, as needed or desired.

In a particular embodiment, BMC 1690 is included on a main circuit board (such as a baseboard, a motherboard, or any combination thereof) of information handling system 1600 or is integrated onto another element of the information handling system such as chipset 1610, or another suitable element, as needed or desired. As such, BMC 1690 can be part of an integrated circuit or a chipset within information handling system 1600. An example of BMC 1690 includes an iDRAC, or the like. BMC 1690 may operate on a separate power plane from other resources in information handling system 1600 of FIG. 16. Thus BMC 1690 can communicate with the management system via network interface 1694 while the resources of information handling system 1600 are powered off. Here, information can be sent from the management system to BMC 1690 and the information can be stored in a RAM or NVRAM associated with the BMC. Information stored in the RAM may be lost after power-down of the power plane for BMC 1690, while information stored in the NVRAM may be saved through a power-down/power-up cycle of the power plane for the BMC.

Information handling system 1600 can include additional components and additional busses, not shown for clarity. For example, information handling system 1600 can include multiple processor cores, audio devices, and the like. While a particular arrangement of bus technologies and interconnections is illustrated for the purpose of example, one of skill will appreciate that the techniques disclosed herein are applicable to other system architectures. Information handling system 1600 can include multiple central processing units (CPUs) and redundant bus controllers. One or more components can be integrated together. Information handling system 1600 can include additional buses and bus protocols, for example, I²C and the like. Additional components of information handling system 1600 can include one or more storage devices that can store machine-executable code, one or more communications ports for communicating with external devices, and various input and output (I/O) devices, such as a keyboard, a mouse, and a video display.

For purposes of this disclosure, information handling system 1600 can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 1600 can be a personal computer, a laptop computer, a smartphone, a tablet device or other consumer electronic device, a network server, a network storage device, a switch, a router, or another network communication device, or any other suitable device and may vary in size, shape, performance, functionality, and price. Further, information handling system 1600 can include processing resources for executing machine-executable code, such as processor 1602, a programmable logic array (PLA), an embedded device such as a System-on-a-Chip (SoC), or other control logic hardware. Information handling system 1600 can also include one or more computer-readable media for storing machine-executable code, such as software or data.

Although FIG. 15 shows example blocks of method 1500 in some implementations, method 1500 may include additional blocks, fewer blocks, different blocks, or differently arranged blocks than those depicted in FIG. 15. Those skilled in the art will understand that the principles presented herein may be implemented in any suitably arranged processing system. Additionally, or alternatively, two or more of the blocks of method 1500 may be performed in parallel. For example, blocks 1535 and 1540 of method 1500 may be performed in parallel.

In accordance with various embodiments of the present disclosure, the methods described herein may be implemented by software programs executable by a computer system. Further, in an exemplary, non-limited embodiment, implementations can include distributed processing, component/object distributed processing, and parallel processing. Alternatively, virtual computer system processing can be constructed to implement one or more of the methods or functionalities as described herein.

When referred to as a “device,” a “module,” a “unit,” a “controller,” or the like, the embodiments described herein can be configured as hardware. For example, a portion of an information handling system device may be hardware such as, for example, an integrated circuit (such as an Application Specific Integrated Circuit (ASIC), a Field Programmable Gate Array (FPGA), a structured ASIC, or a device embedded on a larger chip), a card (such as a Peripheral Component Interface (PCI) card, a PCI-express card, a Personal Computer Memory Card International Association (PCMCIA) card, or other such expansion card), or a system (such as a motherboard, a system-on-a-chip (SoC), or a stand-alone device).

The present disclosure contemplates a computer-readable medium that includes instructions or receives and executes instructions responsive to a propagated signal; so that a device connected to a network can communicate voice, video, or data over the network. Further, the instructions may be transmitted or received over the network via the network interface device.

While the computer-readable medium is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding or carrying a set of instructions for execution by a processor or that cause a computer system to perform any one or more of the methods or operations disclosed herein.

In a particular non-limiting, exemplary embodiment, the computer-readable medium can include a solid-state memory such as a memory card or other package that houses one or more non-volatile read-only memories. Further, the computer-readable medium can be a random-access memory or other volatile re-writable memory. Additionally, the computer-readable medium can include a magneto-optical or optical medium, such as a disk or tapes, or another storage device to store information received via carrier wave signals such as a signal communicated over a transmission medium. A digital file attachment to an e-mail or other self-contained information archive or set of archives may be considered a distribution medium that is equivalent to a tangible storage medium. Accordingly, the disclosure is considered to include any one or more of a computer-readable medium or a distribution medium and other equivalents and successor media, in which data or instructions may be stored.

Although only a few exemplary embodiments have been described in detail above, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents but also equivalent structures.

What is claimed is:

1. A printed circuit board, comprising:
a via configured to provide electrical connectivity between layers of the printed circuit board and having at least a portion of the via removed within a tolerance of a variable; and
a test coupon configured to detect a via stripping issue associated with the via, wherein the via stripping issue occurs when the portion of the via is removed outside of the tolerance of the variable.

2. The printed circuit board of claim 1, wherein the variable includes depth.

3. The printed circuit board of claim 1, wherein the variable includes backdrill misregistration.

4. The printed circuit board of claim 1, wherein the variable includes backdrill deflection.

5. The printed circuit board of claim 1, wherein the variable includes drill speed.

6. The printed circuit board of claim 1, wherein the test coupon includes a test point.

7. The printed circuit board of claim 6, wherein the test coupon is configured to couple with a test equipment via the test point.

8. The printed circuit board of claim 7, wherein the test equipment is used to measure insertion loss versus frequency.

9. The printed circuit board of claim 7, wherein the test equipment is a vector network analyzer.

10. The printed circuit board of claim 8, wherein the insertion loss is analyzed to determine if there is resonance in the insertion loss.

11. The printed circuit board of claim 1, wherein the test coupon is used to test for the variable.

12. An information handling system comprising:
a printed circuit board comprising:
a via configured to provide electrical connectivity between layers of the printed circuit board and having at least a portion removed within a tolerance of a variable; and
a test coupon configured to provide electrical communication to detect a via stripping issue associated with the via, wherein the via stripping issue occurs when the portion of the via is removed outside the tolerance of the variable.

13. The information handling system of claim 12, wherein the test coupon includes a test point.

14. The information handling system of claim 13, wherein the test coupon is configured to couple with a test equipment.

15. The information handling system of claim 14, wherein the test equipment is used to measure insertion loss.

16. The information handling system of claim 14, wherein the test equipment is a vector network analyzer.

17. The information handling system of claim 15, wherein the insertion loss is analyzed to determine if there is resonance in the insertion loss.

18. The information handling system of claim 12, wherein the test coupon is used to test for the variable.

19. A method comprising:
providing a printed circuit board comprising:
a via providing electrical connectivity between layers of the printed circuit board and having at least a portion removed within a tolerance of a variable; and
a test coupon providing electrical communication for detecting a via stripping issue associated with the via, wherein the via stripping issue occurs when the portion of the via is removed outside the tolerance of the variable; and
failing qualification of a manufacturer of the printed circuit board in response to detecting the via stripping issue.

20. The method of claim 19, wherein a test equipment is used to measure insertion loss.
